(19) United States
(12) Patent Application Publication
(10) Pub. No.: US 2006/0121683 A1
(43) Pub. Date: Jun. 8, 2006

(54) Point source diffusion for avalanche photodiodes

(75) Inventors: Daniel A. Francis, Oakland, CA (US); Richard P. Ratowsky, Berkeley, CA (US); Ashish K. Verma, San Jose, CA (US); Sunil Thomas, Mountain View, CA (US); Roman Dimitrov, San Jose, CA (US)

Correspondence Address: WORKMAN NYDEGGER;(F/K/A WORKMAN NYDEGGER & SEELEY), 60 EAST SOUTH TEMPLE, 1000 EAGLE GATE TOWER, SALT LAKE CITY, UT, 84111, US

(73) Assignee: Finisar Corporation

(21) Appl. No.: 11/007,558

(22) Filed: Dec. 8, 2004

(51) Int. Cl. H01L 21/20

(52) U.S. Cl. 438/380

(57) ABSTRACT

Systems and methods for controlling edge gain in avalanche photodiodes. During fabrication of an avalanche photodiode, the photodiode is diffused with a dopant. The mask used for the dopant includes a plurality of openings such that the dopant diffuses within the photodiode to create a plurality of interconnected spheres. The diffusion front has a shape to introduce an edge effect into the center of the photodiode. The diffusion front ameliorates the edge effect by introducing the edge effect into the center of the photodiode.

### RELATED APPLICATIONS

Not applicable.

### BACKGROUND OF THE INVENTION

1. The Field of the Invention

The present invention relates to the field of optical communications. More particular, embodiments of the invention relate to photodiodes including avalanche photodiodes.

2. Related Technology

In optical networks, a receiver is typically needed to convert an incident optical signal into an electrical signal. The receiver accomplishes this task using a device known as a photodetector. A photodetector generates an electrical current that is related to the optical power of the incident optical signal.

A photodiode is a common example of a photodetector. A photodiode typically has a pn junction to create a depletion region that is enhanced by the application of a reverse bias voltage. Often, a lightly doped intrinsic semiconductor is introduced at the pn junction to form a pin photodiode. In a pin photodiode, the intrinsic layer can enhance the frequency response of the photodiode. A pin photodiode may be limited, however, in the sense that one photon only generates one electron upon absorption.

In avalanche photodiodes (APDs), the APD can be subjected to a much higher electric field. As a result of this electric field, an electron generated in response to a photon can generate additional electrons. In other words, an electron creates an avalanche effect and the APD has gain. Electrons generated by a photon are accelerated by the electric field and collide with neutral atoms. These collisions generate new carriers. This process is often referred to as collision ionization and leads to the gain of an APD.

It is typically desirable for an APD to demonstrate constant gain across the APD. Unfortunately, gain at the edges of an APD is usually higher than the gain at the center of the APD. This phenomenon occurs because the electric field at the edges of the device is higher than at the center. Attempts to make the edge gain more constant and account for the adverse effects of edge gain include ion implantation, double diffused junction, etching of curved surfaces prior to diffusion or double infusion, and the like. The edge gain can limit the performance of an APD. The edge gain can also adversely affect the yield of acceptable APDs during manufacture.

One conventional method for forming an APD to limit the impact of edge gain uses double diffusion. This method includes forming a first wide mask and then doping the APD. Those skilled in the art will appreciate that “doping” involves the addition of a particular type of impurity in order to achieve a desired n-conductivity or p-conductivity. The first mask is removed and a second, narrower mask is deposited and a deeper doping is performed. This method controls edge effect by creating a thinner diffusion region at the edge of the APD, increasing the distance from the diffusion region at the edge to the underlying charge layer. Another conventional method for controlling the edge effect is the etching of curved surfaces prior to diffusion.

Each of these methods, however, as well as others known in the art but not mentioned herein, requires multiple steps to form a diffusion region. Whenever additional steps are required in the production of devices such as APDs, the cost has a corresponding increase. In addition, complicated methods with multiple steps are difficult to control during fabrication and typically correspond to reduced yields.

### BRIEF SUMMARY OF AN EMBODIMENT OF THE INVENTION

These and other limitations are overcome by the present invention, which relates to systems and methods for controlling edge gain in photodiodes. In avalanche photodiodes (APDs), the edge effect typically limits the gain of the APD. Embodiments of the invention include a diffusion layer with a diffusion front that reduces or eliminates the effect of edge gain in an avalanche photodiode.

An avalanche photodiode is a multilayer structure that typically includes a substrate, an absorber layer formed over the substrate, a charge layer formed over the absorber layer, and an avalanche layer formed over the charge layer. During manufacture of the avalanche photodiode, a mask is formed on the avalanche layer. Openings are then formed in the mask. The openings permit a dopant to diffuse into the avalanche layer to form a diffusion layer. The mask also typically includes guard rings in addition.

The openings are sized and space such that a diffusion sphere forms beneath each opening in the mask. The diffusion of the dopant occurs such that the diffusion spheres interconnect. The diffusion front is formed by the diffusion spheres and therefore forms an uneven surface with a multitude of convex protrusions. In other words, a distance between the diffusion front and the charge layer varies in the center of the avalanche photodiode as well as at the edge of the avalanche photodiode.

As a result, the center of the avalanche photodiode also exhibits the edge gain for a given optical mode. Because both the center of the avalanche photodiode exhibits a response that is similar to the response at the edges, the impact of edge gain is reduced or eliminated.

In one embodiment, a distance between the interconnected diffusion spheres is less that the optical mode being detected by the avalanche photodiode. In one embodiment, the distance between diffusion spheres is 30 percent smaller than the optical mode. When the optical mode covers more than one full diffusion sphere at any given time, the effects of non-uniformity in the diffusion layer are reduces or eliminated.

The edge effect works because the electric field is enhances at the corners of the biased diffusion layer. In a conventional avalanche photodiode, the decrease in breakdown voltage occurs sooner at the edges than in the center. The diffusion spheres decreases the breakdown voltage in the center and thereby ameliorates the edge effect at the edges of the avalanche photodiode.

These and other advantages and features of the present invention will become more fully apparent from the following description and appended claims, or may be learned by the practice of the invention as set forth hereinafter.

### BRIEF DESCRIPTION OF THE DRAWINGS

To further clarify the above and other advantages and features of the present invention, a more particular description of the invention will be rendered by reference to specific embodiments thereof which are illustrated in the appended drawings. It is appreciated that these drawings depict only typical embodiments of the invention and are therefore not to be considered limiting of its scope. The invention will be described and explained with additional specificity and detail through the use of the accompanying drawings in which:

FIG. 1 illustrates the structure of a of a conventional avalanche photodiode;

FIG. 2 is a two dimensional plot of a cross section of photodiode intensity, demonstrating that edge gain is higher than the center gain of a conventional avalanche photodiode;

FIG. 3 is an example of a top view of a mask used for point source diffusion in an avalanche photodiode;

FIG. 4 illustrates the diffusion front formed in an avalanche photodiode using the mask illustrated in FIG. 3;

FIG. 5 illustrates two dimensional plots of photodiode intensity, demonstrating that the effects of edge gain in a photodiode with a diffusion front illustrated in FIG. 4; and

FIG. 6 illustrates an exemplary method for manufacturing an avalanche photodiode with the diffusion front illustrated in FIG. 4.

### DETAILED DESCRIPTION OF EMBODIMENTS OF THE INVENTION

The present invention relates to avalanche photodiodes (APDs) and more particularly to a point source diffusion method for controlling the edge effect in avalanche photodiodes. As previously stated, the edge effect is a phenomenon where the edges of the active region of an APD typically have higher gain that the center of an APD. The gain of the photodiode associated with the edges can limit the usefulness of the APD by overwhelming the gain of the center, introducing excessive noise, therefore limiting the achievable gain before avalanche breakdown.

The ability to control the edge effect is further complicated by conventional methods that use multiple diffusions. Conventionally, multiple diffusions are used to smooth the diffusion profile by masking the edge. According to embodiments of the invention, the diffusion is controlled such that the mechanism that causes the edges to breakdown first is implemented across the entire photodiode. As a result, embodiments of the invention can cause the center of the photodiode to breakdown simultaneously or about the same time with the edges. The discrepancy between the breakdown of the edges and the breakdown of the center of the APD is reduced. In addition, the diffusion can be performed as a single step, thereby reducing the complexity of manufacturing the APD using multiple diffusion steps, reducing cost associated with the manufacture of the APD, and increasing the yield.

Embodiments of the invention use a diffusion through a patterned mask that creates a diffusion front across the center of the APD that is similar to the diffusion front at the edge of the APD. This type of a diffusion front in the active device is no longer smooth and continuous. In other words, embodiments of the invention introduce the edge effect into the center of the APD. Forming this type of a diffusion front in an APD can advantageously reduce the breakdown voltage of the APD and also limit the adverse effects of edge gain in APDs. The edge effect is ameliorated.

Reference will now be made to the drawings to describe various aspects of exemplary embodiments of the invention. It is to be understood that the drawings are diagrammatic and schematic representations of such exemplary embodiments, and are not limiting of the present invention, nor are they necessarily drawn to scale.

In the following description, numerous specific details are set forth in order to provide a thorough understanding of the present invention. It will be obvious, however, to one skilled in the art that the present invention may be practiced without these specific details. In other instances, well-known aspects of optoelectronic systems have not been described in particular detail in order to avoid unnecessarily obscuring the present invention.

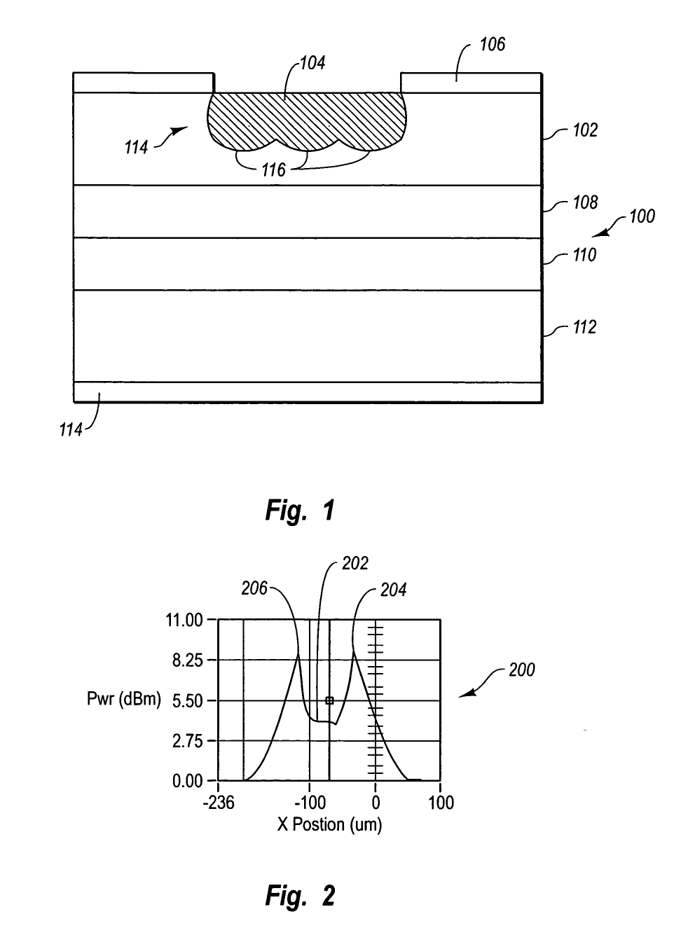

FIG. 1 an exemplary structure of a typical avalanche photodiode. While APD structures vary greatly in form and methods of production, FIG. 1 provides a good background for the present discussion of APDs. As depicted, APD 100 includes an avalanche layer 102 having a diffusion region 104 formed therein with a diffusion front 114. The diffusion front 114 is not flat, but has multiple convex shaped protrusions 116. The diffusion front 114 of the APD 100 is formed from multiple openings in the mask. The diffusion from a single opening, in one embodiment, creates a sphere shaped diffusion into the APD 100. When the sphere like diffusions from the openings are combined, the spheres are interconnected and form the diffusion front 114, which has an uneven surface.

Advantageously, the distance of the diffusion front 114 to the underlying layers of the APD varies across the surface of the diffusion front 114. This is similar to what is experienced at the edges of conventional avalanche photodiodes. As a result, the edge effect is experienced in the center of the APD 100 and the adverse impact of the edge effect is reduced or eliminated. The breakdown may also be reduced.

Underneath the avalanche layer 102 is a charge layer 108. Underneath the charge layer 108 is an absorber layer 110, which in turn is over a substrate 112. A bottom electrode 114 and a top electrode, which are oppositely charged, apply a voltage across the APD. The charge layer 108 helps moderate the electrical field.

The avalanche layer 102 may be formed of a material such as, for example, InP or InAlAs. The avalanche layer 102 is where the electrons initially generated by the incident photons accelerate and multiply as they move through the APD active region. The diffusion region 104 is formed in the center region of avalanche layer 102 with an implanted dopant material, for example zinc, to form, for example, a p+ InP diffusion region 104. As depicted by mask 106, the diffused area of the diffusion region is a direct result of the position of the mask 106. The absorber layer 110 is formed on a substrate 112. As the name implies, the absorber layer is where an optical signal is absorbed.

As previously stated, the diffusion region 104 is conventionally formed in one or more steps in an attempt to control edge gain. Edge gain results from the fact that the electric field is higher at the edges of the APD active region, which has slightly less depth than at the center. FIG. 2 illustrates an example of the edge gain in a conventional APD that does not have the advantage of the diffusion illustrated in FIG. 1.

The graph 200 plots the power of the current generated in the APD as a function of position on the APD. Near the center 202 of the APD, the gain is relatively constant. As the graph 200 moves away from the center of the photodiode, the edges 206 illustrate that the gain is substantially higher than at the center 202. During operation of the APD, the gain at the edge overcomes the gain at the center and limits the use of the APD. The edge effect occurs in part because the electric field is higher at the edges of the APD.

Returning to FIG. 1, after the avalanche layer 102 (FIG. 1) is formed, the avalanche photodiode can be prepared for diffusion. In one embodiment, the diffusions described herein can be accomplished in a single step and multiple diffusions are not necessarily required. Diffusion is performed using selected dopants. In preparation for diffusing a dopant into the avalanche layer 102, a mask is first formed on the avalanche layer 102.

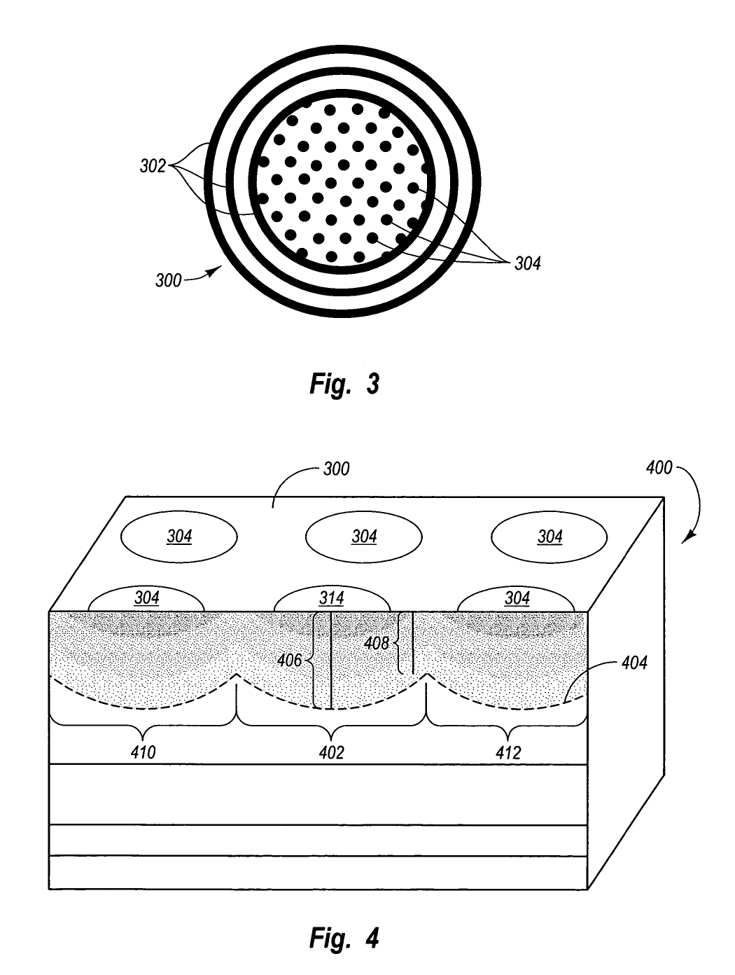

FIG. 3 illustrates a top view of a patterned mask that has been formed on the surface of an avalanche photodiode. The mask 300 is typically formed from a suitable material such as silicon oxide or silicon nitride. The mask material can then be etched using photolithography or lift-off methods, for example, to form desired patterns. Further details for forming masks are well known in the art and are not discussed herein in greater detail to avoid obscuring the invention.

The mask 300 includes openings 304 that permit diffusion of the selected dopant to occur into at least the avalanche layer of the APD. The openings are configured to create a diffusion front with an uneven surface. The openings 304 in the mask 300 create a spherical diffusion underneath each opening 304. The diffusion occurs under the openings 304 and not under the mask 300. The resulting dopant front enables the edge breakdown to occur at points within the center of the APD and not exclusively at the edges. Thus, the mask 300 is filled with diffusion openings 304. IN one example, the edge has guard rings 302 to avoid surface breakdown.

The sphere like diffusions are performed across the active part of the APD through the openings 304. Thus, the active device does not have a smooth and continuous center diffusion front. The curvature of the diffusion front obtained from the mask 300 enhances the edge effect in the center of the APD and decreases the breakdown of the APD. In order to counter any effect of non uniform sensitivity that may be generated from the mask 300 or from the resulting diffusion, the distance between openings 304 or between the resulting diffusion spheres should be smaller than the optical mode such that the optical mode covers more than one full diffusion sphere at any time. In one embodiment, the distance between openings 304 should be approximately 30 percent smaller than the optical mode. The diffusion spheres are preferably interconnected. This enables free carriers to be swept out.

The arrangement of the openings in the mask 300 can vary and may depend on the optical mode being detected. The distance between openings, the size of the opening, the shape of the openings, and the like, can be determined, for example, using the expected optical mode, the rate of diffusion into the avalanche layer, the dopant being used, the thickness of the layers in the APD, and the like or any combination thereof.

FIG. 4 illustrates an example of the diffusion spheres that are formed in an APD using the mask 300. FIG. 4 depicts the openings 304 in the mask 300 as described in FIG. 3. The diffusion spheres 402, 410, and 412 resulting from the diffusion become interconnected and ultimately form the diffusion front 404 for the APD 400. Although FIG. 4 illustrates two dimensions of the diffusion spheres 402, 410, and 412, one of skill in the art can appreciate that the diffusion spheres are three dimensional. One of skill in art can also appreciate that the density or concentration of the dopant within the diffusion region may vary. The concentration is typically highest near the openings in the mask.

The diffusion front 404, represented by the dashed line, demonstrates that the diffusion front has a dimpled surface. In FIG. 4, the diffusion sphere 402 corresponds at least in part to diffusion through the opening 314. The depth 406 of the diffusion sphere 402 is greater than the depth 408 of the diffusion sphere 402. As a result of this difference in depth for each diffusion sphere, the diffusion front for each diffusion sphere appears similar to the diffusion front that forms at the edge of conventional APDs. This creates an edge effect within the center of the APD 400 for each of the diffusion spheres. The curvature of the diffusion front 404 also enhances the edge effect and decreases the breakdown voltage. In addition, the diffusion spheres 402, 410, and 412 are interconnected.

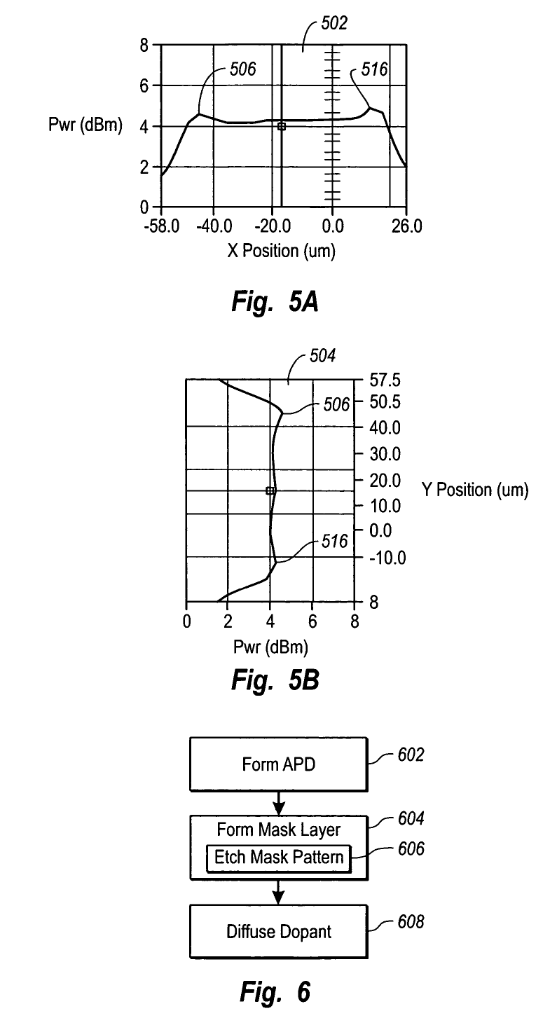

FIG. 5 illustrates the effect of the diffusion spheres on the edge effect in comparison to FIG. 2. The plots 502 (X Position) and 506 (Y Position) represent a position view of the current intensity of an APD with diffusion spheres. The peaks 506 are reduced compared to the peaks illustrated in FIG. 2. This indicates that the gain has been more linearized across the APD and that the adverse consequences of edge effect for conventional APDs has been reduced or eliminated.

FIG. 6 illustrates an exemplary method for forming an ADP in accordance with embodiments described herein. The method of FIG. 6 also controls diffusion depth in a single diffusion step and reduces the impact of the edge effect. The method begins by forming an avalanche photodiode 602. This can include, for example, forming an absorber layer that absorbs incident light over a substrate. A charge layer is then formed over the absorber layer. The avalanche layer is formed over the charge layer and is the layer where multiplication occurs.

After the APD is formed, a mask layer is formed on the avalanche layer 602. Forming the mask layer can include etching a mask pattern 606, such as the mask pattern illustrated in FIG. 3, into the mask layer. Next, a dopant is diffused 608 through the openings etched into the mask layer. The mask pattern is selected to permit the dopant to diffuse into the avalanche layer to form diffusion spheres in one embodiment. The resulting diffusion front formed by these interconnected diffusion spheres is an uneven surface with multiple protrusions. In one embodiment, the protrusions are convex shaped.

One embodiment of the mask used to perform the diffusion of a dopant into the APD includes a plurality of openings. Other configurations as described above are possible. The mask pattern is selected such that the resulting diffusion front provides or approximates an edge effect within the center portion of the APD.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A method for manufacturing an avalanche photodiode, the method comprising:
forming an absorber layer over a substrate;
forming an avalanche layer over the absorber layer;
forming a mask over a surface of the avalanche layer to block a dopant;
forming a mask pattern in the mask, the mask pattern including a plurality of openings; and
diffusing the dopant through the plurality of openings in the mask pattern, wherein the dopant diffuses into the avalanche layer to form a diffusion front having one or more protrusions.

2. A method as defined in claim 1, wherein forming a mask pattern in the mask further comprises forming the plurality of openings a distance between openings is less than an optical mode detected by the avalanche photodiode.

3. A method as defined in claim 1, wherein forming a mask pattern in the mask further comprises forming one or more guard rings in the mask.

4. A method as defined in claim 1, wherein a distance between openings is 30 percent or more less than an optical mode detected by the avalanche photodiode.

5. A method as defined in claim 1, wherein the absorber layer comprises InAlAs and the avalanche layer comprises InP.

6. A method as defined in claim 1, wherein diffusing the dopant through the plurality of openings in the mask pattern further comprises one or more of:
forming the diffusion front to have an uneven surface; and
forming diffusion spheres beneath each opening.

7. A method as defined in claim 6, further comprising interconnecting the diffusion spheres.

8. An avalanche photodiode comprising:
a substrate;
an absorber layer formed over the substrate;
a charge layer formed over the absorber layer;
an avalanche layer formed over the charge layer; and
a diffusion layer formed within the avalanche layer using a dopant, the diffusion layer having a diffusion front configured to produce an edge effect in a center of the avalanche photodiode.

9. An avalanche photodiode as defined in claim 8, wherein the diffusion layer is diffused into the avalanche layer using a mask having a plurality of openings formed therein.

10. An avalanche photodiode as defined in claim 9, wherein the dopant diffuses through each of the plurality of openings to form a plurality diffusions spheres in the avalanche region.

11. An avalanche photodiode as defined in claim 10, wherein the plurality of diffusion spheres are interconnected and form the diffusion front.

12. An avalanche photodiode as defined in claim 11, wherein a distance between a first diffusion sphere and a second diffusion sphere is less than an optical mode detected by the avalanche photodiode.

13. An avalanche photodiode as defined in claim 12, wherein the optical mode covers at least one diffusion sphere.

14. An avalanche photodiode as defined in claim 8, wherein the absorber layer comprises InAlAs and the avalanche layer comprises InP and wherein the charge layer comprises InP and the dopant comprises zinc.

15. An avalanche photodiode as defined in claim 8, wherein a distance between the diffusion front and the charge layer varies within center of the avalanche photodiode and at an edge of the avalanche photodiode.

16. An avalanche photodiode comprising:
a substrate;
an absorber layer that absorbs an incident optical mode;
a charge layer;
an avalanche layer;
a diffusion layer comprising a plurality of interconnected diffusion sphere, wherein the interconnected diffusion spheres form a diffusion front that has a distance that varies from the charge layer, wherein the interconnected diffusion spheres are formed in the avalanche layer by diffusing a dopant through a plurality of openings formed in a mask, the mask being formed on the avalanche layer prior to diffusing the dopant.

17. An avalanche photodiode as defined in claim 16, wherein the diffusion front includes a plurality of convex protrusions, each convex protrusion corresponding to one of the diffusion spheres.

18. An avalanche photodiode as defined in claim 16, wherein the absorber layer comprises InAlAs, the charge layer comprises InP, the avalanche layer comprises InP, and the dopant comprises zinc.

19. An avalanche photodiode as defined in claim 16, wherein a concentration of dopant in the diffusion layer varies according at least to depth of the diffusion layer.

20. An avalanche photodiode as defined in claim 16, wherein a distance between diffusion spheres is less that the optical mode.

21. An avalanche photodiode as defined in claim 20, wherein a diffusion sphere is at least 30 percent smaller than the optical mode.

22. An avalanche photodiode as defined in claim 16, wherein the diffusion front produces an edge effect within a center of the photodiode to reduce a breakdown of the avalanche photodiode.
